(19) United States
(12) Patent Application Publication
(10) Pub. No.: US 2026/0045522 A1
(43) Pub. Date: Feb. 12, 2026

(54) HYDRODREN FUEL CELL VOLTAGE MONITOR INTERFACE

(71) Applicant: GM GLOBAL TECHNOLOGY OPERATIONS LLC, DETROIT, MI (US)

(72) Inventors: Matthew J. Beutel, Webster, NY (US); Brian Podczervinski, West Bloomfield, MI (US); David Prettenhofer, Michigan Center, MI (US)

(21) Appl. No.: 18/798,148

(22) Filed: Aug. 8, 2024

(51) Int. Cl. H01M 8/0254; B60L 50/72; B60L 50/75; G01R 31/3835; H01M 8/0276; H01M 8/04537

(52) U.S. Cl. CPC H01M 8/0254; B60L 50/72; G01R 31/3835; H01M 8/0276; H01M 8/04559; B60L 50/75; H01M 2250/20

(57) ABSTRACT

Aspects of the disclosure include a hydrogen fuel cell voltage monitor interface utilizing spring-loaded contacts and methods of using the same. An exemplary vehicle includes an electric motor and a fuel cell stack electrically coupled to the electric motor. The fuel cell stack includes a plurality of bipolar plates. Each bipolar plate includes one or more cell voltage measurement tabs. A first set of bipolar plates includes a first positioning of the cell voltage measurement tabs and a second set of bipolar plates includes a second positioning of the cell voltage measurement tabs offset with respect to the first positioning of the cell voltage measurement tabs. The fuel cell stack includes a plurality of insulating subgasket layers alternating with the plurality of bipolar plates. An edge of each cell voltage measurement tab is molded to define a semi-spherical pocket for landing a spring-loaded contactor of a measurement device.

### INTRODUCTION

The present disclosure relates to hydrogen fuel cells and fuel cell voltage monitoring, and particularly to a hydrogen fuel cell voltage monitor interface utilizing spring-loaded contacts.

Hydrogen fuel cells and related technologies have emerged as a promising clean energy solution, offering high efficiency and zero emissions for various applications ranging from transportation (e.g., personal and commercial vehicles, shipping, aircraft, etc.) to stationary power generation. In a hydrogen fuel cell, hydrogen enters through an anode, where it's split into protons and electrons. The protons pass through an electrolyte membrane, while electrons flow through an external circuit, generating electricity. At the cathode, protons, electrons, and oxygen combine to produce water. Hydrogen fuel cells are typically implemented in fuel cell stacks—assemblies of multiple individual hydrogen fuel cells connected in series to increase overall voltage and power output.

As research in this field progresses, understanding and optimizing fuel cell stack performance has become crucial for widespread adoption and commercialization. One critical aspect of fuel cell stack operation is the monitoring and control of cell voltages, referred to as cell voltage monitoring (CVM), as cell voltage directly impacts overall system performance and durability. CVM allows researchers and engineers to assess the health and efficiency of individual cells within a stack. Another important measurement technique is hydrogen adsorption/desorption (HAD) measuring, as HAD measurements provide a direct measurement of the available surface area for electrochemical reactions that are key to fuel cell performance and a diagnostic measure of crossover current and shorting values of individual cells.

### SUMMARY

In one exemplary embodiment a vehicle includes an electric motor and a fuel cell stack electrically coupled to the electric motor. The fuel cell stack includes a plurality of bipolar plates. Each bipolar plate includes one or more cell voltage measurement tabs. A first set of bipolar plates includes a first positioning of the cell voltage measurement tabs and a second set of bipolar plates includes a second positioning of the cell voltage measurement tabs offset with respect to the first positioning of the cell voltage measurement tabs. The fuel cell stack includes a plurality of insulating subgasket layers alternating with the plurality of bipolar plates. An edge of each cell voltage measurement tab is molded to define a semi-spherical pocket for landing a spring-loaded contactor of a measurement device.

In addition to one or more of the features described herein, in some embodiments, each bipolar plate of the plurality of bipolar plates is formed by joining an anode half plate and a cathode half plate.

In some embodiments, the edge of each cell voltage measurement tab is molded to define the semi-spherical pocket by molding the anode half plate over a first end of a forming tool and molding the cathode half plate over a second end of the forming tool.

In some embodiments, an insulator spacing block having one or more through holes sized to accommodate the spring-loaded contactor of the measurement device.

In some embodiments, each insulating subgasket layer of the plurality of insulating subgasket layers includes a corrugated edge.

In some embodiments, the insulator spacing block includes one or more alignment teeth positioned to align to the respective corrugated edges of the plurality of insulating subgasket layers.

In some embodiments, the through holes are offset to position spring-loaded contactors against the first positioning of the cell voltage measurement tabs and the second positioning of the cell voltage measurement tabs offset with respect to the first positioning of the cell voltage measurement tabs.

In another exemplary embodiment a fuel cell stack includes a plurality of bipolar plates. Each bipolar plate includes one or more cell voltage measurement tabs. A first set of bipolar plates includes a first positioning of the cell voltage measurement tabs and a second set of bipolar plates includes a second positioning of the cell voltage measurement tabs offset with respect to the first positioning of the cell voltage measurement tabs. The fuel cell stack includes a plurality of insulating subgasket layers alternating with the plurality of bipolar plates. An insulator spacing block having one or more alignment holes is positioned to accommodate one or more corresponding alignment tabs of the bipolar plates.

In some embodiments, each bipolar plate of the plurality of bipolar plates is formed by joining an anode half plate and a cathode half plate.

In some embodiments, the insulator spacing block further includes one or more measurement tab slots positioned to accommodate one or more corresponding cell voltage measurement tabs of the bipolar plates.

In some embodiments, the insulator spacing block further includes one or more through holes sized to accommodate the spring-loaded contactor of the measurement device.

In some embodiments, the through holes are offset to position spring-loaded contactors against the first positioning of the cell voltage measurement tabs and the second positioning of the cell voltage measurement tabs offset with respect to the first positioning of the cell voltage measurement tabs.

In some embodiments, each of the one or more measurement tab slots includes one or more channels.

In some embodiments, the one or more channels are positioned and sized to accommodate a tip of a spring-loaded contactor of the measurement device.

In yet another exemplary embodiment a method can include forming a plurality of bipolar plates. Each bipolar plate includes one or more cell voltage measurement tabs. A first set of bipolar plates includes a first positioning of the cell voltage measurement tabs and a second set of bipolar plates includes a second positioning of the cell voltage measurement tabs offset with respect to the first positioning of the cell voltage measurement tabs. The method includes forming a plurality of insulating subgasket layers alternating with the plurality of bipolar plates. The method includes molding an edge of each cell voltage measurement tab to define a semi-spherical pocket for landing a spring-loaded contactor of a measurement device.

In some embodiments, each bipolar plate of the plurality of bipolar plates is formed by joining an anode half plate and a cathode half plate.

In some embodiments, the edge of each cell voltage measurement tab is molded to define the semi-spherical pocket by molding the anode half plate over a first end of a forming tool and molding the cathode half plate over a second end of the forming tool.

In some embodiments, an insulator spacing block having one or more alignment holes is positioned to accommodate one or more corresponding alignment tabs of the bipolar plates.

In some embodiments, the method includes forming an insulator spacing block having one or more through holes sized to accommodate the spring-loaded contactor of the measurement device.

In some embodiments, each insulating subgasket layer of the plurality of insulating subgasket layers includes a corrugated edge.

In some embodiments, the insulator spacing block includes one or more alignment teeth positioned to align to the respective corrugated edges of the plurality of insulating subgasket layers.

The above features and advantages, and other features and advantages of the disclosure are readily apparent from the following detailed description when taken in connection with the accompanying drawings.

### BRIEF DESCRIPTION OF THE DRAWINGS

Other features, advantages and details appear, by way of example only, in the following detailed description, the detailed description referring to the drawings.

FIG. 1 is a vehicle configured in accordance with one or more embodiments;

FIG. 2A illustrates an example portion of a fuel cell stack in accordance with one or more embodiments;

FIG. 2B illustrates an example cut-away view of the fuel cell stack of FIG. 2A in accordance with one or more embodiments;

FIG. 2C illustrates an example detailed cut-away view of a portion of the fuel cell stack of FIG. 2B in accordance with one or more embodiments;

FIG. 3A illustrates an example view of the bipolar plates of FIG. 2A prior to installation of an insulator spacing block in accordance with one or more embodiments;

FIG. 3B illustrates an example view of the bipolar plates of FIG. 3A after installation of the insulator spacing block in accordance with one or more embodiments;

FIG. 3C illustrates an example view of the bipolar plates along the line A-A of FIG. 3B in accordance with one or more embodiments;

FIG. 3D illustrates an example view of the bipolar plates along the line B-B of FIG. 3B in accordance with one or more embodiments;

FIG. 4A illustrates an example schematic view of an insulator spacing block in accordance with one or more embodiments;

FIG. 4B illustrates an example rear view of the insulator spacing block of FIG. 4A;

FIG. 4C illustrates an example front view of the insulator spacing block of FIG. 4A;

FIG. 4D illustrates an example side view of the insulator spacing block of FIG. 4A;

FIG. 5A illustrates an example view of a spring-loaded contactor pressed against an edge of a cell voltage measurement tab in accordance with one or more embodiments;

FIG. 5B illustrates an example view of a pocket of a cell voltage measurement tab in accordance with one or more embodiments;

FIGS. 5C and 5D illustrate example views of a pocket of a cell voltage measurement tab during an interface with a spring-loaded contactor in accordance with one or more embodiments;

FIG. 6A illustrates an example view of bipolar plates after forming pockets in accordance with one or more embodiments;

FIG. 6B illustrates an example view of bipolar plates after forming pockets in accordance with one or more embodiments;

FIG. 6C illustrates an example view of bipolar plates during a hydrogen adsorption/desorption (HAD) measurement operation in accordance with one or more embodiments;

FIG. 7A illustrates an example view of a fuel cell stack during a cell voltage monitoring (CVM) measurement operation in accordance with one or more embodiments;

FIG. 7B illustrates an example view of a fuel cell stack during a HAD measurement operation in accordance with one or more embodiments;

FIG. 7C illustrates an example view of a fuel cell stack during a CVM measurement operation in accordance with one or more embodiments;

FIG. 8. is a computer system according to one or more embodiments; and FIG. 9 is a flowchart in accordance with one or more embodiments.

### DETAILED DESCRIPTION

The following description is merely exemplary in nature and is not intended to limit the present disclosure, its application or uses. It should be understood that throughout the drawings, corresponding reference numerals indicate like or corresponding parts and features.

Understanding and optimizing fuel cell stack performance has become crucial for widespread adoption and commercialization of hydrogen fuel cell technologies. Two of the most important techniques for assessing fuel cell quality and performance are cell voltage monitoring (CVM) and hydrogen adsorption/desorption (HAD) measuring. CVM allows researchers and engineers to assess the health and efficiency of individual cells within a hydrogen fuel cell stack, while HAD measurements are used to evaluate the hydrogen storage capabilities and surface properties of fuel cell materials.

Bipolar plates (BPPs) play a vital role in fuel cell stacks, serving multiple functions such as distributing reactant gases, removing reaction products, conducting electrical current between cells, and providing mechanical support. In the context of CVM and HAD measurements specifically, BPPs are instrumental, as when conducting CVM, the bipolar plates act as electrically conductive interfaces between adjacent cells, allowing for the measurement of voltage across individual cells. This enables researchers to identify underperforming cells, detect potential issues such as membrane degradation or catalyst poisoning, and optimize stack performance. The conductive nature of BPPs ensures accurate voltage readings while maintaining electrical connectivity throughout the stack. For HAD measurements, including modified hydrogen adsorption/desorption (MHAD) techniques, BPPs play a crucial role in gas distribution and current collection. HAD and MHAD measurements are used to evaluate the electrochemically active surface area (ECSA) of catalyst layers, which is a key parameter in assessing fuel cell performance. The flow field designs incorporated into BPPs ensure uniform gas distribution across the active area, allowing for accurate HAD and MHAD measurements.

In short, the integration of bipolar plates in fuel cell stacks is fundamental to conducting accurate and reliable cell voltage monitoring and hydrogen adsorption/desorption measurements. As research in hydrogen fuel cell technology advances, optimizing BPP design will continue to be a critical driver in improving overall stack performance and durability. Unfortunately, current BPP designs are somewhat limited. One of the current challenges in fuel cell stack design, and BPP designs specifically, is improving electrical coupling to the CVM and HAD tap points. For example, ensuring alignment of pogo-pins and/or pogo-pin boards to CVM/HAD contact points in the stacking direction (with and without cell repeat tolerances) is difficult due in part to carryover alignment issues from upstream blade style tab/insulator designs. Another somewhat related challenge involves finding a solution to stack configurations having nonuniform board/plate distributions (e.g., board to board spacing in a fuel cell stack may not be consistent throughout a given stack). Packaging is yet another challenge, as sufficiently tall CVM/HAD contact points result in stacked BPP packaging interference—in short, special packing and/or separators can be required for shipping BPPs to prevent CVM/HAD damage as the BPP contact points can be taller than the uncompressed metal bead seal elevation (e.g., in one example configuration the socket features can be ˜1.8 mm while the uncompressed metal bead seal elevation can be ˜1.3 mm). Moreover, even when not considering contact point issues, the dimensionally small cell repeat distance or plate spacing pitch (e.g., 0.9 to 1.2 mm) between cells, coupled with limited space to make electrical contact (e.g., commercially available pogo-pin diameters of 2 mm), create packaging challenges for the application.

This disclosure introduces a hydrogen fuel cell voltage monitor interface utilizing spring-loaded contacts. Rather than relying upon a conventional blade style contactor (also referred to as pinch grips) that takes cell voltage measurements across the top surface of alternating blade/space tabs, an insulating spacer block is provided to guide spring-loaded contacts directly against the flat edge of the measurement tabs of a fuel cell bipolar plate for the purpose of CVM and/or HAD measurements. Advantageously, the insulating spacer block electrically insulates the tabs from electrical creepage and clearance issues and restrains the relatively thin plate tab features from deflecting as force is applied normal to the plate edges. In some embodiments, the bipolar plates described herein are modified to include semi-spherical contact pockets to maximize contact area to ball end spring-loaded contact (pogo-pin) geometries.

Notably, unitized electrode assembly (UEA) subgaskets can be positioned to overlap the BPP edges, thereby taking on a corrugated edge when the BPP content pockets are pushed against the subgasket surface at the stacked cell repeat distance during assembly. One of the advantages of such a construction is that the corrugation effect from the displacement of a semi-rigid flat sheet provides additional strength along the axis of the corrugations. Another advantage of such a construction is that repeating height of the stacked BPP sockets are natively less susceptible to out of position contacts due to bent BPP material-in short, this configuration results in self-correcting and more repeatable positioning of the BPP contact areas for interfacing components or tools engagement as stacked socket heights with subgaskets positioned therebetween constrain the magnitude of displacement allowed. Other advantages are realized and are discussed in greater detail below.

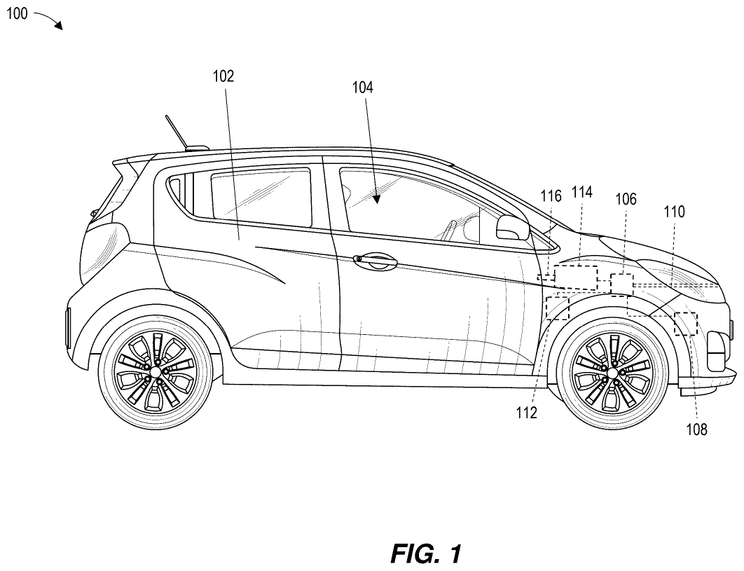

A vehicle, in accordance with an exemplary embodiment, is indicated generally at 100 in FIG. 1. Vehicle 100 is shown in the form of an automobile having a body 102. Body 102 includes a passenger compartment 104 within which are arranged a steering wheel, front seats, and rear passenger seats (not separately indicated). Within the body 102 are arranged a number of components, including, for example, a fuel cell stack 106, a hydrogen fuel storage tank 108, an air intake manifold 110, a battery 112, and an electric motor 114 configured for utilizing electrical energy to provide an output torque to an output component 116 (each shown by projection near the front hood). Fuel cell stack 106 receives a flow of hydrogen or other fuel gas from the hydrogen fuel storage tank 108 and receives a flow of air including oxygen gas from air intake manifold 110. The fuel cell stack 106 may include an air compressor device (not separately indicated) useful to pressurize the air to a desired pressure. The fuel cell stack 106 may provide electrical energy directly to the electric motor 114 and/or the fuel cell stack 106 may provide electrical energy to the battery 112 for storage and later use. The output component 116 may provide the output torque for usage, for example, to provide a motive force to the vehicle 100. The fuel cell stack 106, hydrogen fuel storage tank 108, air intake manifold 110, battery 112, and electric motor 114 are shown for ease of illustration and discussion only. It should be understood that the configuration, location, size, arrangement, etc., of these components is not meant to be particularly limited, and all such configurations (including multi-motor configurations) are within the contemplated scope of this disclosure. Moreover, while the present disclosure is discussed primarily in the context of a fuel cell stack 106 configured for the vehicle 100, aspects described herein can be similarly incorporated within any system (vehicle, building, or otherwise) having a hydrogen fuel cell-based power and/or energy storage system(s), and all such configurations and applications are within the contemplated scope of this disclosure. As will be detailed herein, the fuel cell stack 106 includes bipolar plates designed to interface with an insulating spacer block that is configured to guide spring-loaded contacts directly against the flat edge of the measurement tabs of the respective bipolars plates for the purpose of CVM and/or HAD measurements.

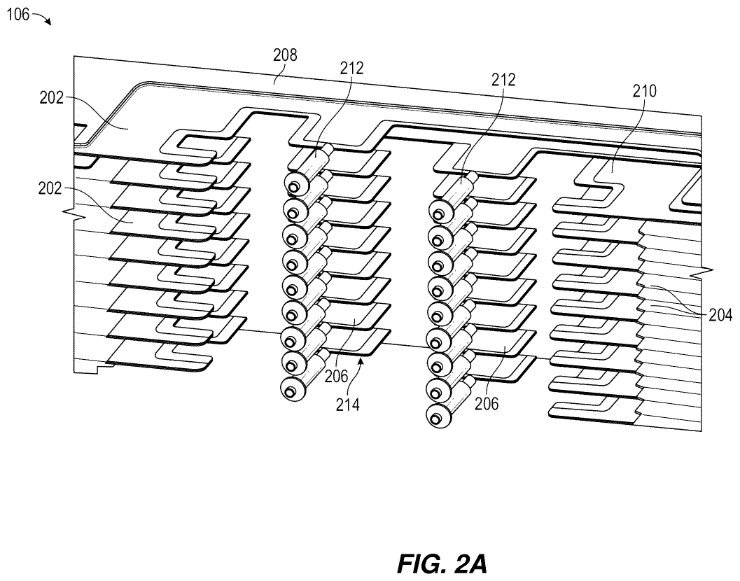

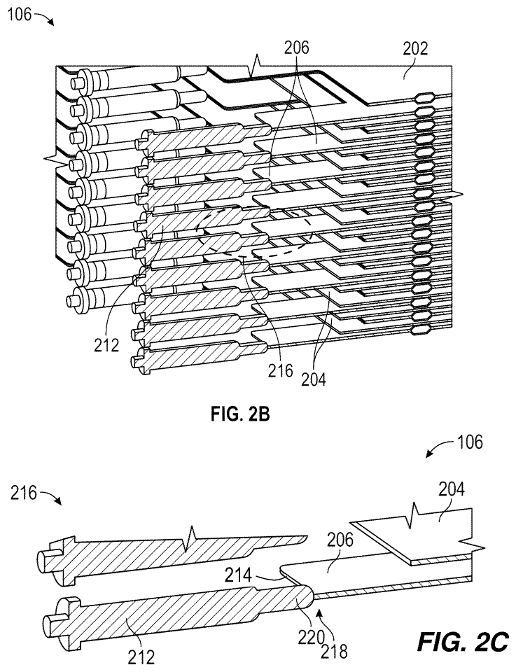

FIG. 2A illustrates an example portion of a fuel cell stack 106 in accordance with one or more embodiments. The number of individual fuel cells (not separately indicated) and their configuration in the fuel cell stack 106 is not meant to be particularly limited, and any number of fuel cells can be combined in the fuel cell stack 106 to generate a desired power output. For example, a fuel cell stack 106 for a vehicle (e.g., vehicle 100 of FIG. 1) can have two hundred or more stacked fuel cells. The fuel cell stack 106 receives a cathode input gas, typically a flow of air forced through the fuel cell stack 106 by a compressor (refer to the discussion of FIG. 1). Not all of the oxygen is consumed by the fuel cell stack 106 and some of the air can be output as a cathode exhaust gas that may include water as a stack by-product. The fuel cell stack 106 also receives an anode hydrogen input gas that flows into the anode side of the fuel cell stack 106. In each fuel cell in the fuel cell stack 106, the anode and cathode typically include finely divided catalytic particles, for example platinum (Pt), supported on carbon particles and mixed with an ionomer. The catalytic mixture is deposited on opposing sides of a membrane. The combination of the anode catalytic mixture, the cathode catalytic mixture, and the membrane define a membrane electrode assembly (MEA) of the respective fuel cell.

As shown in FIG. 2A, the fuel cell stack 106 includes a series of bipolar plates 202. In some embodiments, each cell in the fuel cell stack 106 is defined by a pair of bipolar plates 202 (one anode side bipolar plate and one cathode side bipolar plate) sandwiching a MEA (not separately indicated). In some embodiments, the bipolar plates 202 and the MEAs are positioned between two end plates (not separately indicated). In some embodiments, each fuel cell is flanked by two bipolar plates 202, one on the anode side and one on the cathode side, and the bipolar plates 202 conduct electricity between the adjacent cells of the fuel cell stack 106, allowing the fuel cell stack 106 to generate higher voltages. While not meant to be particularly limited, in some embodiments, the bipolar plates 202 serve as both separators and connectors. The bipolar plates 202 separate the anode of one cell from the cathode of the adjacent cell, preventing the mixing of reactant gases (hydrogen and oxygen). In this configuration, bipolar plates 202 conduct electrical current from one cell to the next, allowing for the series connection of cells to achieve a desired voltage and/or power output. In some embodiments, the bipolar plates 202 contain flow channels that distribute hydrogen to the anode and oxygen to the cathode uniformly across the active area of each cell, ensuring efficient electrochemical reactions. The bipolar plates 202 also aid in managing heat generated during fuel cell operation and can provide structural integrity and mechanical support to the fuel cell stack 106 (ensuring, e.g., that the cells are properly compressed and aligned). In some embodiments, the bipolar plates 202 are made of a composite material, such as graphite, where two plate halves are separately molded and then glued together so that anode flow channels are provided at one side of one of the plate halves, cathode flow channels are provided at an opposite side of the other plate half, and optionally, cooling fluid flow channels are provided between the plate halves. In some embodiments, two separate plate halves are stamped and then welded together so that anode flow channels are provided at one side of one of the plate halves, cathode flow channels are provided at an opposite side of the other plate half, and cooling fluid flow channels are provided between the plate halves.

As further shown in FIG. 2A, in some embodiments, the fuel cell stack 106 includes insulating subgasket layers 204 (also referred to as UEA subgaskets). In some embodiments, the insulating subgasket layers 204 are used to seal edges of the MEA to prevent gas leakage and to provide electrical insulation between adjacent bipolar plates 202. The insulating subgasket layers 204 can be made of a range of suitable semi-rigid polymers and/or plastic films, such as various rubbers (e.g., silicone rubber, fluorocarbon rubber, etc.) and elastomers (e.g., polyolefin elastomers, fluoroelastomers, etc.).

In some embodiments, the bipolar plates 202 include cell voltage measurement tabs 206. Cell voltage measurement tabs 206 are conductive protrusions and/or contact points placed on (or integrated with) the bipolar plates 202 within the fuel cell stack 106 to provide access points for measuring the voltage of each individual cell in the fuel cell stack 106. In some embodiments, the cell voltage measurement tabs 206 are designed to provide electrical contact to the active components (not separately indicated) of each cell.

As further shown in FIG. 2A, in some embodiments, the bipolar plates 202 include two alternating configurations for the cell voltage measurement tabs 206. Specifically, the bipolar plates 202 can include type A plates 208 alternating with type B plates 210. In some embodiments, the positioning of the cell voltage measurement tabs 206 in the type A plates 208 is offset with respect to the positioning of the cell voltage measurement tabs 206 in the type B plates 210, to allow for electrical creepage and clearance (arcing) requirements. Observe that, in this configuration, the bipolar plates 202 and cell voltage measurement tabs 206 are positioned such that a plurality of spring-loaded contactors 212 can be applied axially, via a spring-loaded contactor force, to respective edges 214 of the cell voltage measurement tabs 206.

FIG. 2B illustrates an example cut-away view of the fuel cell stack 106 of FIG. 2A in accordance with one or more embodiments. FIG. 2C illustrates an example detailed cut-away view of a portion 216 of the fuel cell stack 106 of FIG. 2B in accordance with one or more embodiments. As shown in FIGS. 2B and 2C, a point of electrical contact 218 is made between edge 214 of a cell voltage measurement tab 206 and a tip portion 220 of the spring-loaded contactor 212.

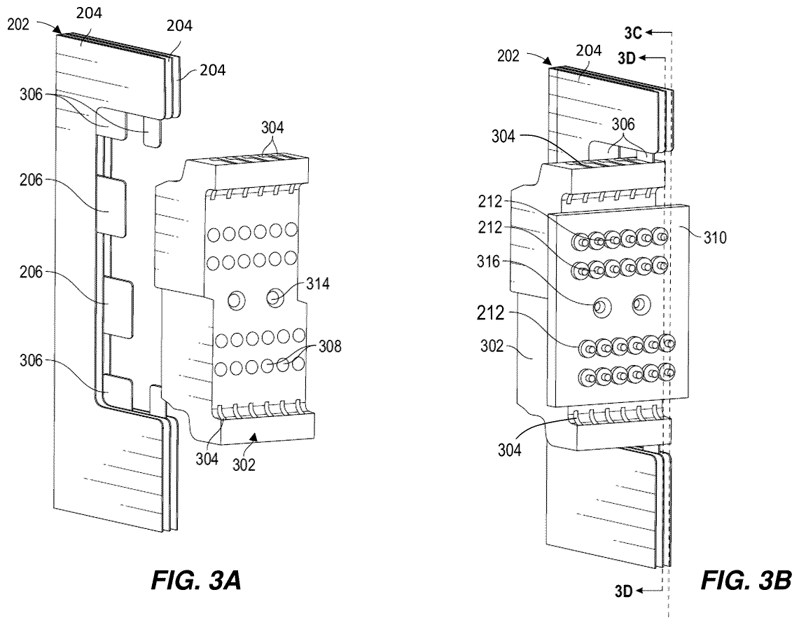

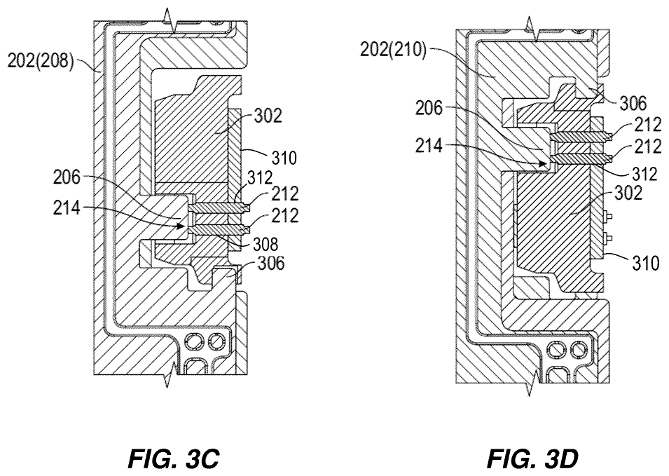

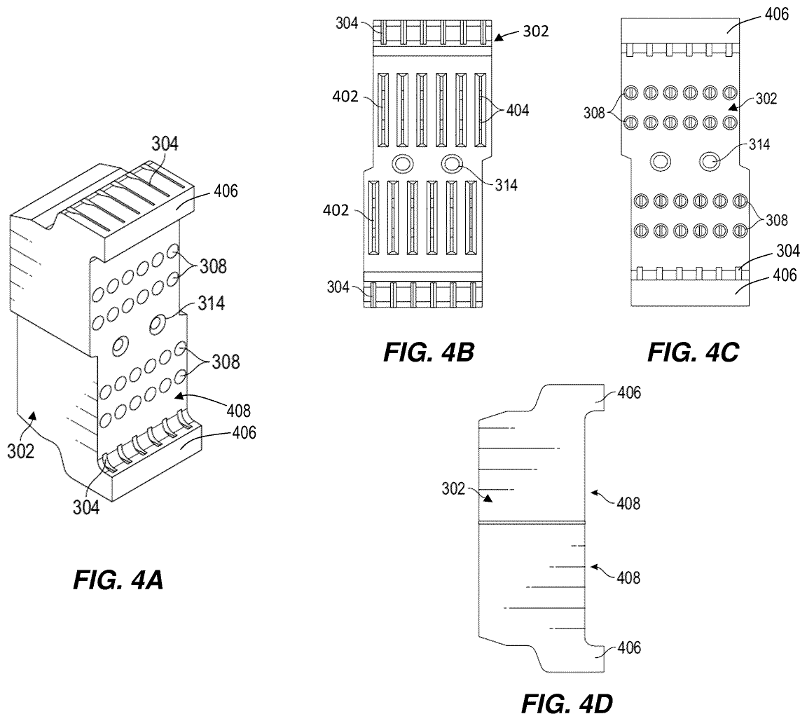

FIG. 3A illustrates an example view of bipolar plates 202 (e.g., the bipolar plates 202 of FIG. 2A) prior to installation of an insulator spacing block 302 in accordance with one or more embodiments. The insulator spacing block 302 is discussed in greater detail with respect to FIGS. 4A-4D. FIG. 3B illustrates an example view of the bipolar plates 202 of FIG. 3A after installation of the insulator spacing block 302 in accordance with one or more embodiments. FIG. 3C illustrates an example view of the bipolar plates 202 along the line A-A of FIG. 3B in accordance with one or more embodiments. FIG. 3D illustrates an example view of the bipolar plates 202 along the line B-B of FIG. 3B in accordance with one or more embodiments.

As shown in FIGS. 3A-3D, the insulator spacing block 302 can include one or more alignment openings (or slots) 304 positioned to fit over and/or otherwise accommodate one or more corresponding alignment tabs 306 (also referred to as retention features or metal retention features) of the bipolar plates 202. The number of alignment openings 304 need not be particularly limited. For example, as shown, 12 alignment openings 304 are arranged in two banks of 6 holes each (6 along the top of the insulator spacing block 302 and 6 along the bottom of the insulator spacing block 302). Other configurations (e.g., having different numbers of alignment openings 304) are possible and all such configurations are within the contemplated scope of this disclosure.

In some embodiments, the insulator spacing block 302 can include one or more measurement tab slots 402 (refer to FIG. 4B) positioned to fit over and/or otherwise accommodate one or more corresponding cell voltage measurement tabs 206 of the bipolar plates 202.

In some embodiments, the insulator spacing block 302 can include one or more through holes 308 sized to accommodate respective ones of the plurality of spring-loaded contactors 212. The number of the through holes 308 need not be particularly limited. In some embodiments, the through holes 308 are arranged to position the spring-loaded contactors 212 against cell voltage measurement tabs 206 of alternating type A plates 208 and type B plates 210 (refer to FIGS. 3C and 3D). In other words, in some embodiments, some of the through holes 308 can be offset with respect to others of the through holes 308, in a similar manner as the cell voltage measurement tabs 206 of alternating type A plates 208 and type B plates 210 can be offset with respect to one another. For example, as shown, 24 through holes 308 are arranged in four rows having six through holes 308 each, with a pair of rows (12 total through holes) positioned for the cell voltage measurement tabs 206 of type A plates 208 and another pair of rows (12 total through holes) positioned for the cell voltage measurement tabs 206 of type B plates 210. Other configurations (different numbers of through holes 308, different numbers of rows, etc.) are possible and all such configurations are within the contemplated scope of this disclosure.

In some embodiments, the insulator spacing block 302 is configured to interface with a tooling board 310 (e.g., a printed circuit board) having one or more through holes 312 sized and positioned to accommodate respective ones of the plurality of spring-loaded contactors 212 and to align to the one or more through holes 308 of the insulator spacing block 302, thereby allowing the spring-loaded contactors 212 to be inserted through the tooling board 310 and through the underlying insulator spacing block 302 to contact the cell voltage measurement tabs 206. In some embodiments, the insulator spacing block 302 includes one or more alignment holes 314 and the tooling board 310 includes one or more alignment holes 316 to aid in the alignment of the respective components during installation.

Referring now to FIGS. 3C and 3D, once installed, the insulator spacing block 302 and the tooling board 310 serve to guide the spring-loaded contactors 212 to the edges 214 of the cell voltage measurement tabs 206 of the bipolar plates 202. Observe that the bipolar plate 202 in FIG. 3C is a type A plate 208 and the bipolar plate 202 in FIG. 3D is a type B plate 210, and that the positioning of the cell voltage measurement tab 206 in the type A plate 208 is offset with respect to the positioning of the cell voltage measurement tab 206 in the type B plate 210. In this configuration, the insulator spacing block 302 and the tooling board 310 work cooperatively to repeatably position any number of edge contacts (that is, edges 214 of the cell voltage measurement tabs 206) to a corresponding plurality of spring-loaded contactors 212, to electrically insulate the cell voltage measurement tabs 206 from electrical creepage and clearance issues, and to restrain the cell voltage measurement tabs 206 from deflecting as force is applied normal to the edges 214 during a measurement operation.

FIG. 4A illustrates an example schematic view of an insulator spacing block 302 (e.g., the insulator spacing block 302 of FIGS. 3A-3D) in accordance with one or more embodiments. FIG. 4B illustrates an example rear view of the insulator spacing block 302 of FIG. 4A. FIG. 4C illustrates an example front view of the insulator spacing block 302 of FIG. 4A. FIG. 4D illustrates an example side view of the insulator spacing block 302 of FIG. 4A.

As shown in FIGS. 4A-4D, the insulator spacing block 302 can include a plurality of through holes 308, a plurality of alignment holes 314, a plurality of alignment openings 304, and a plurality of measurement tab slots 402. In some embodiments, the measurement tab slots 402 are positioned to fit over and/or otherwise accommodate one or more corresponding cell voltage measurement tabs 206 of the bipolar plates 202 (refer to FIG. 3A).

As shown in FIG. 4B, in some embodiments, the measurement tab slots 402 are sized to allow a cell voltage measurement tabs 206 inserted into the respective slot measurement tab slot 402 to contact two (as shown) or more (not separately shown) of the spring-loaded contactors 212 (refer to FIG. 3B). In some embodiments, each of the measurement tab slots 402 includes one or more (as shown in FIG. 4B, two) channels 404. In some embodiments, each of the channels 404 is positioned and sized to accommodate a tip 220 (refer to FIG. 2C) of one of the spring-loaded contactors 212. In this manner, each of the channels 404 allows for a pair of spring-loaded contactors 212 to contact the edge 214 of the bipolar plates 202.

In some embodiments, the insulator spacing block 302 can include end portions 406 that include the alignment openings 304 and which extend towards the corresponding alignment tabs 306 of the bipolar plates 202 (refer to FIGS. 3A, 3C, and 3D). In some embodiments, the end portions 406 define, in part, a recessed pocket feature 408 that can be used for CVM and/or HAD position and alignment.

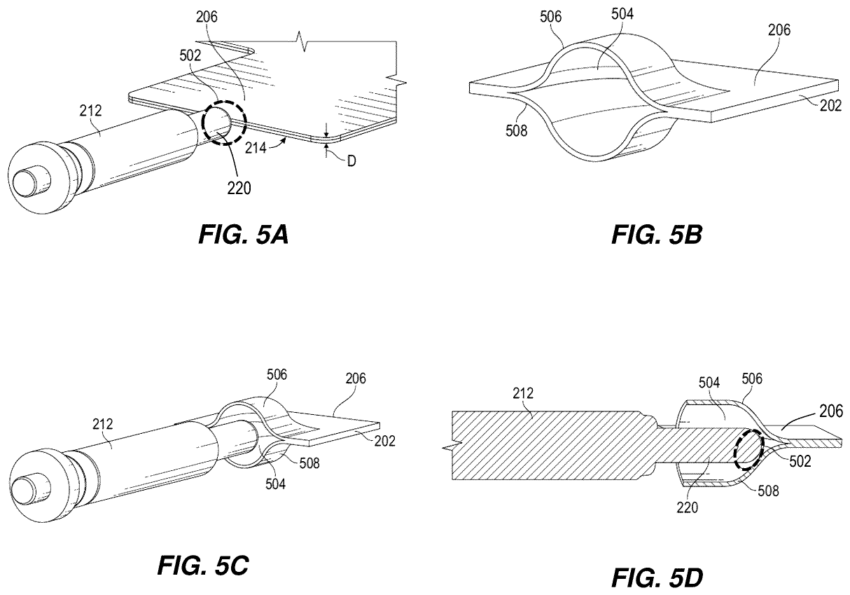

FIG. 5A illustrates an example view of a spring-loaded contactor 212 pressed against an edge 214 of a cell voltage measurement tab 206 in accordance with one or more embodiments. Observe, from FIG. 5A, that a contact interface 502 between the spring-loaded contactor 212 and the edge 214 is natively limited by a thickness D of the edge 214. The thickness D is not particularly limited, but can be less than 3 millimeters (e.g., 0.05 to 3 millimeters, 1 millimeter, etc.). This results in a relatively small contact surface for landing the spring-loaded contactor 212. To address this, in some embodiments, edge 214 is molded to create a pocket 504 (also referred to as a semi-spherical CVM/HAD pocket).

FIG. 5B illustrates an example view of a pocket 504 of a cell voltage measurement tab 206 in accordance with one or more embodiments. In some embodiments, pocket 504 is a semi-spherical pocket. As discussed previously, in some embodiments, a bipolar plate 202 can be formed by joining two half plates 506 and 508 (e.g., via joining an anode half plate to a cathode half plate). In some embodiments, pocket 504 is formed during the joining of the two half plates 506 and 508. For example, in some embodiments, a forming tool (not separately shown) can be placed between the half plates 506 and 508 having a shape and location corresponding to the desired pocket 504. In this manner, the pocket 504 can be formed when the two half plates 506 and 508 are pressed together.

FIGS. 5C and 5D illustrate example views of a pocket 504 of a cell voltage measurement tab 206 during an interface with a spring-loaded contactor 212 in accordance with one or more embodiments. As shown in FIGS. 5C and 5D, a contact interface 502 provided by pocket 504 is increased relative to the contact interface 502 of FIG. 5A. In this manner, pocket 504 increases electrical conduction and is more robust to tooling tolerances as the components are self-aligning and the contact interface 502 is constrained by limiting degrees of positional freedom between the cell voltage measurement tab 206 and the spring-loaded contactor 212.

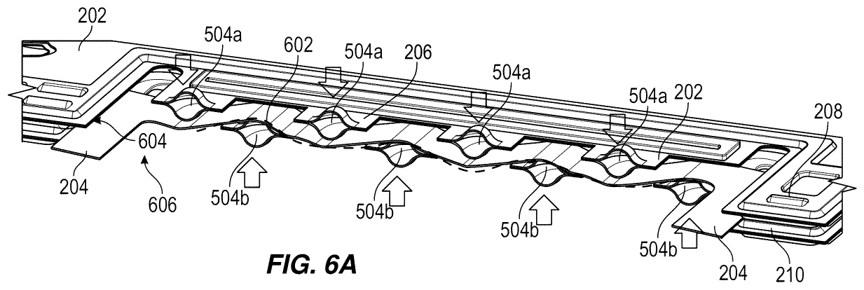

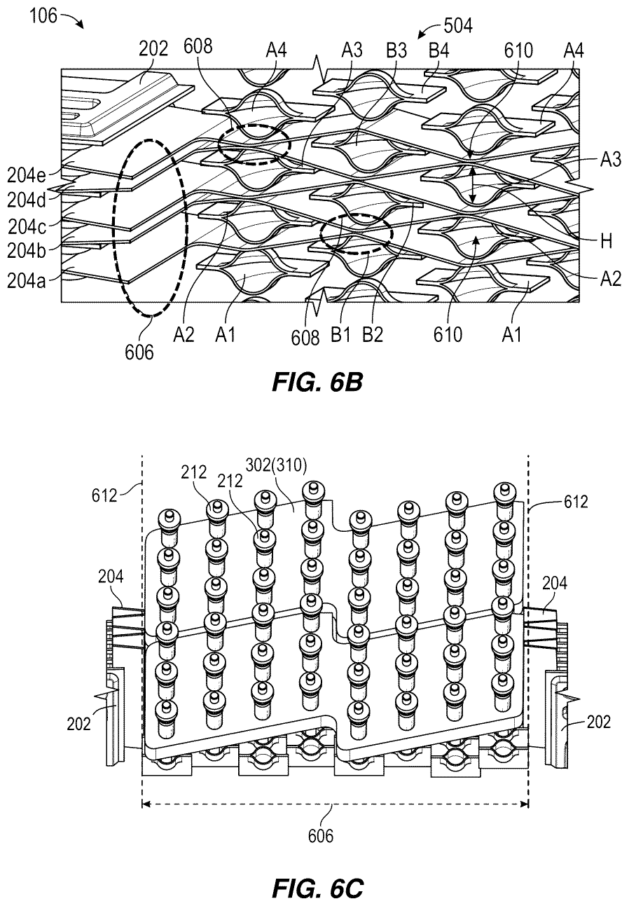

FIG. 6A illustrates an example view of bipolar plates 202 (e.g., the bipolar plates 202 of FIG. 2A) after forming pockets 504 in accordance with one or more embodiments. In some embodiments, the pockets 504 include a first plurality of pockets 504a and a second plurality of pockets 504b. In some embodiments, the first plurality of pockets 504a align to the cell voltage measurement tabs 206 of the type A plates 208. In some embodiments, the second plurality of pockets 504b align to the cell voltage measurement tabs 206 of the type B plates 210.

As further shown in FIG. 6A, the type A plates 208 and the type B plates 210 have been stacked together with an insulating subgasket layer 204 positioned therebetween. In some embodiments, the type A plates 208, the type B plates 210, and the insulating subgasket layer 204 are pressed together during the manufacturing process. Observe, from FIG. 6A, that the insulating subgasket layer 204 overlaps the pockets 504 and will therefore take on a corrugated edge 602 during manufacture as the pockets 504 are pushed into the insulating subgasket layer 204. In some embodiments, the insulating subgasket layer 204 is provided as a flat sheet in a free state that is forced into a corrugated shape (taking on the corrugated edge 602) by the alternating configuration of the pockets 504. Moreover, the insulating subgasket layer 204 overlaps outer plate edges 604 of the bipolar plates 202, thereby defining a pocket 606. While the exact contour of the corrugated edge 602 need not be particularly limited, in some embodiments, the pockets 504 are recessed with respect to pocket 606 for electrical insulation and to mitigate electrical current creepage. In some embodiments, the pockets 504 are positioned to provide a so-called 2× cell-to-cell repeat height such that the corrugated edge 602 takes on a sinusoidal ripple. This type of configuration enables improved visual identification of the recessed socket locations of the pockets 504 and robustness to subgasket folding or covering of the bipolar plates 202 along the socket axis. Alternatively, while both the pockets 504 (BPP sockets) and pocket 606 (sinusoidal subgasket pocket) are shown in FIGS. 6A and 6B as recessed from what would be a contiguous edge (not separately shown) of the bipolar plates 202 or insulating subgasket layer 204 respectively, these features can also be applied inline and not recessed from existing edges (although the bipolar plates 202 and insulating subgasket layers 204 are still required to have some degree of overlap and/or offset for electrical insulation).

FIG. 6B illustrates an example view of bipolar plates 202 (e.g., the bipolar plates 202 of FIG. 2A) after forming pockets 504 in accordance with one or more embodiments. As shown, the pockets 504 are arranged in alternating banks of four pockets 504 (pockets A1, A2, A3, and A4 alternating with pockets B1, B2, B3, and B4), although the exact number of pockets 504 is only illustrative and is not meant to be particularly limited. In some embodiments, the insulating subgasket layers 204 include a plurality of insulating subgasket layers 204a, 204b, 204c, 204d, and 204e, configured and arranged as shown. Specifically, in some embodiments, the insulating subgasket layers 204a, 204b, 204c, 204d, and 204e are configured such that two layers 608 of subgasket insulation material are positioned between each of the pockets 504 having a same alignment (e.g., between the A1 and A2 pockets, between the B3 and B4 pockets, etc.). This configuration lowers the likelihood of a short forming between bipolar plates 202 (e.g., edge shorting). Observe that the plurality of insulating subgasket layers 204a, 204b, 204c, 204d, and 204e further define a pocket 606 relative to the outer plate edges 604 (refer to FIG. 6A).

One advantage of the construction shown in FIG. 6B is a self-correcting positioning of the pockets 504 and the insulating subgasket layers 204. Observe, for example, that a height H of the pockets 504 with two layers 608 of subgasket insulation material natively constrains the magnitude of any displacement allowed between those components due to each of the pockets 504 providing a resistive force 610 towards pockets 504 both above and below each respective pocket 504 (that is, the pockets 504 will resist collapse). The result of this configuration is that any pockets 504 that are initially misaligned will be forced back into alignment by the adjacent pockets 504. As such, this configuration is less susceptible to out of position contact due, for example, to bent BPP material, allowing a more predictable and repeatable positioning of the BPP contact areas for interfacing components or tools engagement (e.g., for CVM and/or HAD measurements).

FIG. 6C illustrates an example view of bipolar plates 202 (e.g., the bipolar plates 202 of FIG. 2A) during a HAD measurement operation in accordance with one or more embodiments. FIG. 6C is provided to show how the pocket 606 defined by the plurality of insulating subgasket layers 204a, 204b, 204c, 204d, and 204e (refer to FIG. 6B) can be used by spring loaded contactor boards (e.g., the insulator spacing block 302 and tooling board 310 of FIGS. 3A and 3B) for alignment. Observe, for example, that the stacked insulating subgasket layers 204a, 204b, 204c, 204d, and 204e provide a planer stack of edges 612 resulting in a recessed pocket feature (e.g., the pocket 606) that can be used for CVM and/or HAD position and alignment.

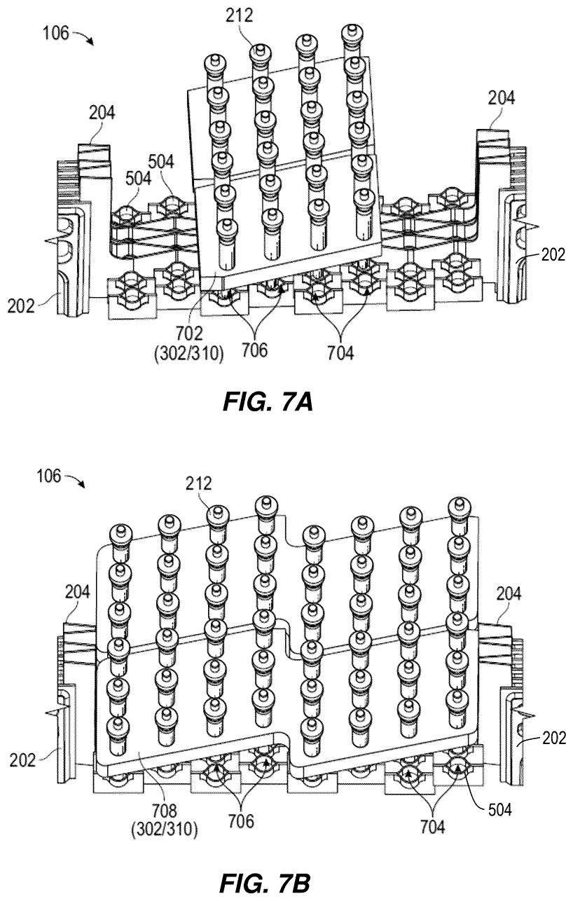

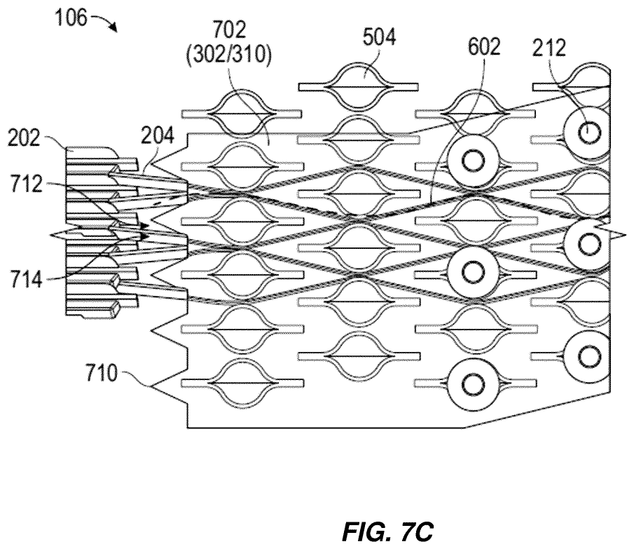

FIG. 7A illustrates an example view of a fuel cell stack 106 (refer to FIG. 2A) during a CVM measurement operation in accordance with one or more embodiments. As shown in FIG. 7A, a CVM module 702 is installed over the pockets 504 of cell voltage measurement tabs 206. The CVM module 702 can include, for example, an insulator spacing block 302 and a tooling board 310 (refer to FIG. 3B). In the configuration shown in FIG. 7A, the CVM module 702 positions the spring-loaded contactors 212 in a staggered skip pattern that places one spring-loaded contactor 212 against each bipolar plate 202 of the fuel cell stack 106 (note that CVM measurements only require one contact per BPP).

Observe that some of the pockets 504 are skipped pockets 704—that is, only a portion of the pockets 504 are used pockets 706. This staggered configuration increases the space for mating components (e.g., an increase of about 2× as compared to conventional straight-line configurations). Moreover, alternating footprints between type A plates 208 and type B plates 210 along with alternating between a predetermined subset (e.g., between two of four as shown) of cell voltage measurement tabs 206 results in a 4× cell repeat spacing for pogo contact locations.

FIG. 7B illustrates an example view of a fuel cell stack 106 (refer to FIG. 2A) during a HAD measurement operation in accordance with one or more embodiments. As shown in FIG. 7B, a HAD module 708 is installed over the pockets 504 of the cell voltage measurement tabs 206. The HAD module 708 can include, for example, an insulator spacing block 302 and a tooling board 310 (refer to FIG. 3B). In the configuration shown in FIG. 7B, the HAD module 708 positions the spring-loaded contactors 212 in a staggered skip pattern that repeats every four pockets 504, thereby placing two spring-loaded contactors 212 against each bipolar plate 202 of the fuel cell stack 106 (note that HAD measurements require two contacts per BPP). This configuration offers at least a 4× spacing improvement over conventional straight-line configurations. Observe that some of the pockets 504 are skipped pockets 704 and some are used pockets 706, in a similar manner as discussed with respect to the CVM module 702 of FIG. 7A.

FIG. 7C illustrates an example view of a fuel cell stack 106 (refer to FIG. 2A) during a CVM measurement operation in accordance with one or more embodiments. As shown in FIG. 7C, a CVM module 702 is installed over the pockets 504 of cell voltage measurement tabs 206. The CVM module 702 can include, for example, an insulator spacing block 302 and a tooling board 310 (refer to FIG. 3B). In the configuration shown in FIG. 7C, the CVM module 702 includes alignment teeth 710 (also referred to as CVM/HAD pogo-pin board teeth). The alignment teeth 710 can be incorporated within any underlying component of the CVM module 702 (e.g., the insulator spacing block 302 and/or tooling board 310). Moreover, while show for a CVM module 702, a HAD module 708 (refer to FIG. 7B) can similarly include alignment teeth 710.

Recall, from FIG. 6A, that the insulating subgasket layers 204 overlap the pockets 504 and will therefore take on a corrugated edge 602 during manufacture as the pockets 504 are pushed into the respective insulating subgasket layers 204. This configuration results, in some embodiments, in the insulating subgasket layers 204 terminating at the bipolar plates 202 in an alternating pattern having stacked subgasket corrugation wide spaces 712 and stacked subgasket corrugation narrow spaces 714. In some embodiments, the CVM module 702 (or HAD module 708) is designed such that the alignment teeth 710 will align with the stacked subgasket corrugation wide spaces 712. This configuration provides an intuitive, straightforward visual and tactile manner to confirm proper positioning of the components of the fuel cell stack 106 (e.g., the insulating subgasket layers 204, pockets 504, etc.).

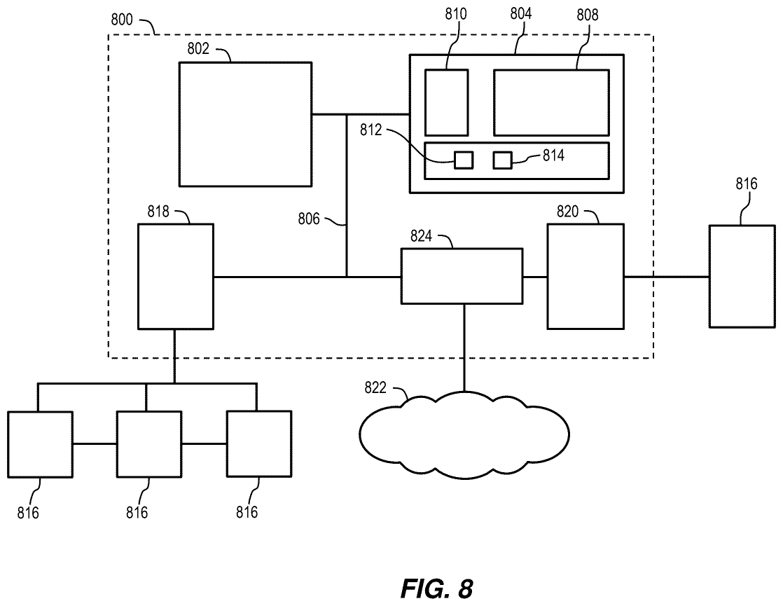

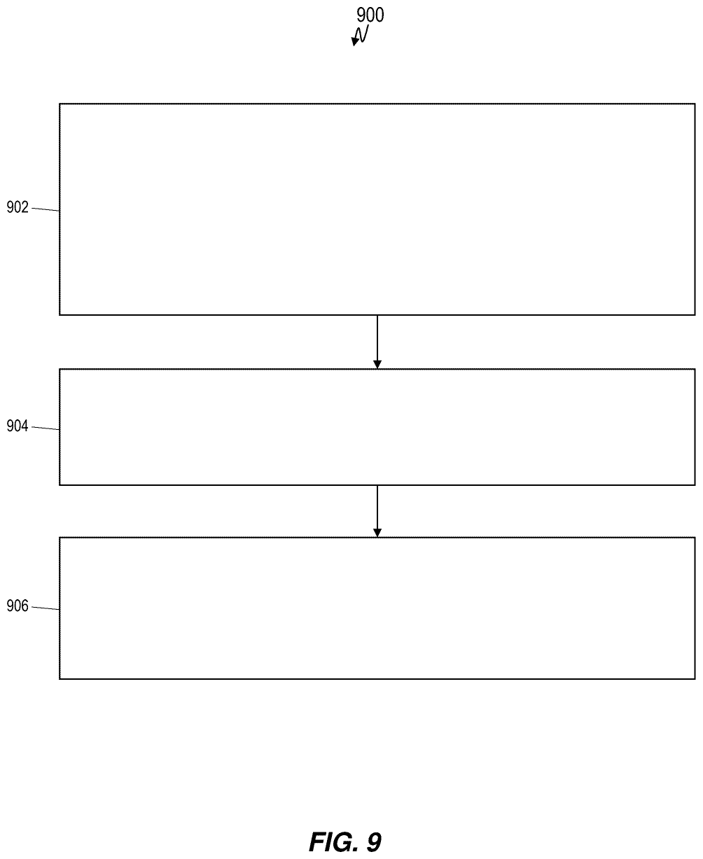

FIG. 8 illustrates aspects of an embodiment of a computer system 800 that can perform various aspects of embodiments described herein. In some embodiments, the computer system(s) 800 can implement and/or otherwise be incorporated within or in combination with a bipolar plate measurement system, such as a CVM module 702 or HAD module 708. For example, in some embodiments, computer system 800 can apply or receive a signal (e.g., voltage, current, etc.) to one (for CVM measurements) or two (for HAD measurements) spring-loaded contactors 212 and underlying pockets 504.

The computer system 800 includes at least one processing device 802, which generally includes one or more processors or processing units for performing a variety of functions, such as, for example, any and/or all of the functions described with respect to FIG. 9. Components of the computer system 800 also include a system memory 804, and a bus 806 that couples various system components including the system memory 804 to the processing device 802. The system memory 804 may include a variety of computer system readable media. Such media can be any available media that is accessible by the processing device 802, and includes both volatile and non-volatile media, and removable and non-removable media. For example, the system memory 804 includes a non-volatile memory 808 such as a hard drive, and may also include a volatile memory 810, such as random access memory (RAM) and/or cache memory. The computer system 800 can further include other removable/non-removable, volatile/non-volatile computer system storage media.

The system memory 804 can include at least one program product having a set (e.g., at least one) of program modules that are configured to carry out functions of the embodiments described herein. For example, the system memory 804 stores various program modules that generally carry out the functions and/or methodologies of embodiments described herein. A module or modules 812, 814 may be included to perform functions related to any of the block diagrams described herein. The computer system 800 is not so limited, as other modules may be included depending on the desired functionality of the computer system 800. As used herein, the term “module” refers to processing circuitry that may include an application specific integrated circuit (ASIC), an electronic circuit, a processor (shared, dedicated, or group) and memory that executes one or more software or firmware programs, a combinational logic circuit, and/or other suitable components that provide the described functionality.

The processing device 802 can also be configured to communicate with one or more external devices 816 such as, for example, a keyboard, a pointing device, and/or any devices (e.g., a network card, a modem, etc.) that enable the processing device 802 to communicate with one or more other computing devices. Communication with various devices can occur via Input/Output (I/O) interfaces 818 and 820.

The processing device 802 may also communicate with one or more networks 822 such as a local area network (LAN), a general wide area network (WAN), a bus network and/or a public network (e.g., the Internet) via a network adapter 824. In some embodiments, the network adapter 824 is or includes an optical network adaptor for communication over an optical network. It should be understood that although not shown, other hardware and/or software components may be used in conjunction with the computer system 800. Examples include, but are not limited to, microcode, device drivers, redundant processing units, external disk drive arrays, RAID systems, and data archival storage systems, etc.

Referring now to FIG. 9, a flowchart 900 for leveraging a hydrogen fuel cell voltage monitor interface utilizing spring-loaded contacts to monitor a fuel cell stack is generally shown according to an embodiment. The flowchart 900 is described in reference to FIGS. 1-8 and may include additional steps not depicted in FIG. 9. Although depicted in a particular order, the blocks depicted in FIG. 9 can be rearranged, subdivided, and/or combined.

At block 902, the method includes forming a plurality of bipolar plates. In some embodiments, each bipolar plate of the plurality of bipolar plates includes one or more cell voltage measurement tabs. In some embodiments, the plurality of bipolar plates includes a first set of bipolar plates having a first positioning of the cell voltage measurement tabs and a second set of bipolar plates having a second positioning of the cell voltage measurement tabs offset with respect to the first positioning of the cell voltage measurement tabs.

At block 904, the method includes forming a plurality of insulating subgasket layers alternating with the plurality of bipolar plates.

At block 906, the method includes molding an edge of each cell voltage measurement tab to define a semi-spherical pocket for landing a spring-loaded contactor of a measurement device.

In some embodiments, each bipolar plate of the plurality of bipolar plates is formed by joining an anode half plate and a cathode half plate.

In some embodiments, the edge of each cell voltage measurement tab is molded to define the semi-spherical pocket by molding the anode half plate over a first end of a forming tool and molding the cathode half plate over a second end of the forming tool.

In some embodiments, the method includes forming an insulator spacing block having one or more through holes sized to accommodate the spring-loaded contactor of the measurement device.

In some embodiments, each insulating subgasket layer of the plurality of insulating subgasket layers includes a corrugated edge.

In some embodiments, the insulator spacing block includes one or more alignment teeth positioned to align to the respective corrugated edges of the plurality of insulating subgasket layers.

The terms “a” and “an” do not denote a limitation of quantity, but rather denote the presence of at least one of the referenced item. The term “or” means “and/or” unless clearly indicated otherwise by context. Reference throughout the specification to “an aspect”, means that a particular element (e.g., feature, structure, step, or characteristic) described in connection with the aspect is included in at least one aspect described herein, and may or may not be present in other aspects. In addition, it is to be understood that the described elements may be combined in any suitable manner in the various aspects.

Additionally, as used in this disclosure, phrases of the form “at least one of an A, a B, or a C,” “at least one of A, B, and C,” and the like, should be interpreted to select at least one from the group that comprises “A, B, and C. ” Unless explicitly stated otherwise in connection with a particular instance in this disclosure, this manner of phrasing does not mean “at least one of A, at least one of B, and at least one of C. ” As used in this disclosure, the example “at least one of an A, a B, or a C,” would cover any of the following selections: {A}, {B}, {C}, {A, B}, {A, C}, {B, C}, and {A, B, C}.

When an element such as a layer, film, region, or substrate is referred to as being “on” another element, it can be directly on the other element or intervening elements may also be present. In contrast, when an element is referred to as being “directly on”another element, there are no intervening elements present.

Unless specified to the contrary herein, all test standards are the most recent standard in effect as of the filing date of this application, or, if priority is claimed, the filing date of the earliest priority application in which the test standard appears.

Unless defined otherwise, technical and scientific terms used herein have the same meaning as is commonly understood by one of skill in the art to which this disclosure belongs.

While the above disclosure has been described with reference to exemplary embodiments, it will be understood by those skilled in the art that various changes may be made and equivalents may be substituted for elements thereof without departing from its scope. In addition, many modifications may be made to adapt a particular situation or material to the teachings of the disclosure without departing from the essential scope thereof. Therefore, it is intended that the present disclosure not be limited to the particular embodiments disclosed, but will include all embodiments falling within the scope thereof.

What is claimed is:

1. A vehicle comprising:
an electric motor; and
a fuel cell stack electrically coupled to the electric motor, the fuel cell stack comprising:
a plurality of bipolar plates, each bipolar plate of the plurality of bipolar plates comprising one or more cell voltage measurement tabs, the plurality of bipolar plates comprising a first set of bipolar plates having a first positioning of the cell voltage measurement tabs and a second set of bipolar plates having a second positioning of the cell voltage measurement tabs offset with respect to the first positioning of the cell voltage measurement tabs; and
a plurality of insulating subgasket layers alternating with the plurality of bipolar plates;
wherein an edge of each cell voltage measurement tab is molded to define a semi-spherical pocket for landing a spring-loaded contactor of a measurement device.

2. The vehicle of claim 1, wherein each bipolar plate of the plurality of bipolar plates is formed by joining an anode half plate and a cathode half plate.

3. The vehicle of claim 2, wherein the edge of each cell voltage measurement tab is molded to define the semi-spherical pocket by molding the anode half plate over a first end of a forming tool and molding the cathode half plate over a second end of the forming tool.

4. The vehicle of claim 1, further comprising an insulator spacing block having one or more through holes sized to accommodate the spring-loaded contactor of the measurement device.

5. The vehicle of claim 4, wherein the through holes are offset to position spring-loaded contactors against the first positioning of the cell voltage measurement tabs and the second positioning of the cell voltage measurement tabs offset with respect to the first positioning of the cell voltage measurement tabs.

6. The vehicle of claim 4, wherein each insulating subgasket layer of the plurality of insulating subgasket layers comprises a corrugated edge.

7. The vehicle of claim 6, wherein the insulator spacing block includes one or more alignment teeth positioned to align to the respective corrugated edges of the plurality of insulating subgasket layers.

8. A fuel cell stack comprising:
a plurality of bipolar plates, each bipolar plate of the plurality of bipolar plates comprising one or more cell voltage measurement tabs, the plurality of bipolar plates comprising a first set of bipolar plates having a first positioning of the cell voltage measurement tabs and a second set of bipolar plates having a second positioning of the cell voltage measurement tabs offset with respect to the first positioning of the cell voltage measurement tabs;
a plurality of insulating subgasket layers alternating with the plurality of bipolar plates; and
an insulator spacing block having one or more alignment holes positioned to accommodate one or more corresponding alignment tabs of the bipolar plates.

9. The fuel cell stack of claim 8, wherein each bipolar plate of the plurality of bipolar plates is formed by joining an anode half plate and a cathode half plate.

10. The fuel cell stack of claim 8, wherein the insulator spacing block further comprises one or more measurement tab slots positioned to accommodate one or more corresponding cell voltage measurement tabs of the bipolar plates.

11. The fuel cell stack of claim 10, wherein the insulator spacing block further comprises one or more through holes sized to accommodate a spring-loaded contactor of a measurement device.

12. The fuel cell stack of claim 11, wherein the through holes are offset to position spring-loaded contactors against the first positioning of the cell voltage measurement tabs and the second positioning of the cell voltage measurement tabs offset with respect to the first positioning of the cell voltage measurement tabs.

13. The fuel cell stack of claim 12, wherein each of the one or more measurement tab slots includes one or more channels.

14. The fuel cell stack of claim 13, wherein the one or more channels are positioned and sized to accommodate a tip of a spring-loaded contactor of the measurement device.

15. A method comprising:
forming a plurality of bipolar plates, each bipolar plate of the plurality of bipolar plates comprising one or more cell voltage measurement tabs, the plurality of bipolar plates comprising a first set of bipolar plates having a first positioning of the cell voltage measurement tabs and a second set of bipolar plates having a second positioning of the cell voltage measurement tabs offset with respect to the first positioning of the cell voltage measurement tabs;
forming a plurality of insulating subgasket layers alternating with the plurality of bipolar plates; and
molding an edge of each cell voltage measurement tab to define a semi-spherical pocket for landing a spring-loaded contactor of a measurement device.

16. The method of claim 15, wherein each bipolar plate of the plurality of bipolar plates is formed by joining an anode half plate and a cathode half plate.

17. The method of claim 16, wherein the edge of each cell voltage measurement tab is molded to define the semi-spherical pocket by molding the anode half plate over a first end of a forming tool and molding the cathode half plate over a second end of the forming tool.

18. The method of claim 15, further comprising forming an insulator spacing block having one or more through holes sized to accommodate the spring-loaded contactor of the measurement device.

19. The method of claim 18, wherein each insulating subgasket layer of the plurality of insulating subgasket layers comprises a corrugated edge.

20. The method of claim 19, wherein the insulator spacing block includes one or more alignment teeth positioned to align to the respective corrugated edges of the plurality of insulating subgasket layers.
